(19) United States
(12) Patent Application Publication
(10) Pub. No.: US 2007/0264598 A1
(43) Pub. Date: Nov. 15, 2007

(54) Method of forming a fine pattern

(75) Inventors: Ching-Yu Chang, Van-Sun (TW); Burn-Jeng Lin, Hsin-Chu (TW); Chin-Hsiang Lin, Hsin-Chu (TW)

Correspondence Address: TUNG & ASSOCIATES;Suite 120, 838 W. Long Lake Road, Bloomfield Hills, MI, 48302, US

(73) Assignee: Taiwan Semiconductor Manufacturing Co., Ltd.

(21) Appl. No.: 11/416,263

(22) Filed: May 1, 2006

(51) Int. Cl. G03F 7/20

(52) U.S. Cl. 430/322; 430/324

(57) ABSTRACT

A process of forming a fine pattern including forming a first photoresist layer over a first layer of a semiconductor device. Portions of the first photoresist layer are exposed causing a photochemical reaction therein. Prior to developing the first photoresist layer, a second photoresist layer is formed over the first photoresist layer, and wherein at least one of the first photoresist layer and second photoresist layer comprises a photo base generator.

### FIELD OF THE INVENTION

The present invention relates to making patterns using photoresist materials. BACKGROUND OF THE INVENTION

Referring now to FIGS. 1A-I, a known method of making a semiconductor device 10 includes providing a first layer 14 to be etched which may overlie a substrate 12 which may be a semiconductor wafer. The substrate 12 may be any material known to those skilled in the art for making semiconductor devices including, but not limited, to silicon, germanium, silicon and germanium, gallium arsenate, silicon carbide and silicon germanium. The first layer 14 to be etched may be an electrically conductive material or a dielectric. The first layer 14 to be etched is a dielectric such as silicon dioxide, or a low dielectric constant material such as SiOC, SiOF, SiC, SiCN. A first sacrificial layer 16 is provided over the first layer 14 to be etched as shown in FIG. 1A.

Referring now to FIG. 1B, a first mask 18 is provided and includes transparent portions 20 for transmitting light therethrough and non-transparent portions 22 for blocking light. Light as indicated by the arrows labeled 21 is shown through the first mask 18 exposing portions of the first sacrificial layer 16. The first sacrificial layer 16 comprises a photoresist material and includes light exposed portions 24 and unexposed portions 26.

Referring now to FIG. 1C, the sacrificial layer 16 is developed and the exposed portions 24 removed leaving openings 28 extending through the first sacrificial layer 16.

Referring now to FIG. 1D, thereafter the first sacrificial layer 16 is treated to increase the resistance of the first sacrificial layer 16 without intermixing to first resist material 30 coating. The treating of the first sacrificial layer 16 may include at least one of irradiation of the first sacrificial layer 16 with infrared light, broad band ultraviolet light, deep ultraviolet light (for example having a wave length ranging from 193-248 nm) extra ultraviolet light (for example having a wave length of 13.5 nm), e-beam and x-rays. The first sacrificial layer 16 is treated with ion implant hardening to increase resistance to first resist layer 30 from mixing. The first sacrificial layer 16 is treated with a chemical to increase the resistance of the first sacrificial layer from mixing with the first resist layer 30, such as, but not limited to, exposing the first sacrificial layer 16 to water vapor and then alkoxysilane gas.

Referring now to FIG. 1E, thereafter, a first photoresist layer 30 is formed over the first sacrificial layer 16 and fills the openings 28 extending through the first sacrificial layer 16.

Referring now to FIG. 1F, thereafter, a second mask 32 which includes transparent portions 34 for transmitting light therethrough and non-transparent portions 36 for blocking light is positioned over the structure of FIG. 1E and light is transmitted through the mask creating exposed portions 38 in the first photoresist and unexposed portions 40 in the first photoresist. As will be appreciated from FIG. 1F, the transparent portions 34 of the second mask 32 are much larger than the transparent portions 20 of the first mask.

Referring now to FIG. 1G, the first photoresist material is developed and the exposed portions removed to provide openings 42 in the first photoresist that communicate with at least one of the openings 28 and the sacrificial layer 16. If desired, some of the openings 28 in the first sacrificial 16 may be blocked by unexposed portions 40 of the first photoresist layer 30. As will be appreciated by FIG. 1G, each opening 42 in the first photoresist layer 30 is vertically aligned with at least one opening 28 in the first sacrificial layer 16. An opening 42 in the first photoresist layer 30 may span a plurality of adjacent openings 28 in the first sacrificial layer 16. Further, the width of the opening 42 in the first photoresist layer 30, generally indicated by arrow B, is greater in all directions than the width of the opening 28 in the first sacrificial layer 16 in all directions. Consequently, the cross-sectional area of the opening 42 in the first photoresist layer 30 is greater than the cross-sectional area of the opening 28 in the first sacrificial layer 16.

Referring now to FIG. 1H, thereafter, the semiconductor device is etched through the openings 42 and 28 to etch openings 44 through the first layer 14. The first photoresist layer 30 is etched substantially by the etching material as will be appreciated by the position of the upper surface 41 of the photoresist layer 30 as originally deposited and the position of the upper surface 43 of the etched first photoresist layer 30. However, due to the treatment of the sacrificial layer 16, the opening pattern 44 is transfer directly from the sacrificial layer 16. This allows for much narrower features and greater packing density of features in the first layer 14. The first layer 14 is silicon dioxide and the etching is accomplished using a plasma etch including CF₄ and CHF₃. The photoresist layer 30 and the sacrificial layer 16 may be exposed in the above embodiments using KrF light as exposure light as well as, G rays, I rays, ArF light and e-beam

Referring now to FIGS. 2A-I, a known method of making a semiconductor device includes providing a first sacrificial layer 16 over a first layer 14 to be etched over a semiconductor substrate 12 as described with respect to FIG. 1A. However, the first sacrificial layer 16 comprises a hard mask such as silicon nitride or silicon oxynitride overlying the first layer 14. A second sacrificial layer 46 is provided over the first sacrificial layer 16. The second sacrificial layer 46 comprises a photoresist material.

Referring now to FIG. 2B, a first mask 18 is provided which again includes transparent portions 20 transmitting light therethrough and non-transparent portions 22. Light is transmitted through the first mask 18 creating exposed portions 48 and unexposed portions 50 in the second sacrificial layer 46. Thereafter, the second sacrificial layer 46 is developed and the exposed portions 48 removed producing openings 52 through the second sacrificial layer 46. The openings 52 expose a portion of the first sacrificial layer 16.

Referring now to FIG. 2D, the first sacrificial layer 16, which is a hard mask, is etched to provide openings 28 extending through the first sacrificial layer 16 exposing portions of the first layer 14. The silicon nitride may be etched with phosphoric acid in the case of a wet etch, or a plasma generated from CF₄ /O₂. The second sacrificial layer 46 is removed.

Referring now to FIG. 2E, a first photoresist layer 30 is formed over the first sacrificial layer 16 so that portions of the photoresist layer fill the openings 28 formed in the first sacrificial layer 16.

Referring now to FIG. 2F, thereafter a second mask 32 is provided including transparent portions 34 for transmitting light therethrough and non-transparent portions 36 for blocking light and light is transmitted through the second mask 32 creating exposed portions 38 in the first photoresist layer 30 and unexposed portions 40 in the first photoresist layer 30.

Referring now to FIG. 2G, thereafter the photoresist layer 30 is developed and the exposed portions 38 removed leaving openings 42 in the first photoresist layer 30. An opening 42 in the first photoresist layer 30 may span a plurality of adjacent openings 28 in the first sacrificial layer 16. Further, the width of the opening 42 in the first photoresist layer 30 generally indicated by arrow B is greater in all directions than the width of the opening 28 in the first sacrificial layer 16 in all directions. Consequently, the cross-sectional area of the opening 42 in the first photoresist layer 30 is greater than the cross-sectional area of the opening 28 in the first sacrificial layer 16.

Referring now to FIG. 2H, thereafter the first layer 14 is etched to provide openings 44 therethrough. As will be appreciated from FIG. 2H, the first photoresist layer 30 is substantially etched as will be appreciated from the location of the upper surface 41 indicated by the dotted line of the first photoresist 30 as originally deposited and the upper surface 43 of the etched first photoresist layer 30. However, because the first sacrificial layer 16 is a hard mask such as silicon nitride, the first sacrificial layer 16 is substantially unaffected by the etching material. This allows for much narrower and more densely packed features to be formed in the first layer 14. Thereafter, the first photoresist layer 30 and the sacrificial layer 16 are removed as shown in FIG. 2I.

FIGS. 3A-E illustrate a known method of making a photoresist structure. A first layer 110 is provided and a first photoresist 112 is provided over the first layer 110. The first layer 10 may be a metallization layer, dielectric layer, or a semiconductor substrate, for example, a silicon wafer. The first photoresist layer 112 is exposed, developed and patterned to produce a plurality of first photoresist features 114. Each of the first photoresist features 114 has an upper surface 116 and at least a first sidewall 118, and typically a second opposite sidewall 120 as shown in FIG. 3B.

Thereafter, as shown in FIG. 3C, a second photoresist 122 is applied over the structure of FIG. 3B. The upper surface 116, the first sidewall 118 and the second sidewall 120, are all covered by the second photoresist material 122.

Thereafter, as shown in FIG. 3D, the structure of FIG. 3C is heated to release an acid in the plurality of individual photoresist features 114. The second photoresist material 122 may be crosslinked upon exposure to the acid released from the plurality of photoresist features 114. The acid diffuses from the upper surface 116, first sidewall 118 and second sidewall 120 outwardly into the second photoresist material 122. Thereafter, the uncrosslinked portions of the second photoresist layer 122 are removed by, for example, developing using a liquid chemical developer to dissolve the soluble regions of the photoresist. The above-described process may be utilized to produce photoresist structures having a relatively narrow gap 148 between structures caused by the crosslinked portion 124 of the first photoresist 112 that extends along each of the first sidewall 118 and the second sidewall 120 from the upper face 16 down to the first layer 110.

Sugino et al., U.S. Pat. No. 6,566,040, issued May 20, 2003, discloses a hole pattern or separation pattern of a first resist that is capable of supplying acid formed on a semiconductor substrate. A crosslinking film is formed on the sidewall of the first substrate pattern to obtain a resist pattern having a reduced hole diameter or separation width. Then, the hole diameter or the separation width is further reduced by causing thermal reflow of the crosslinked film. The semiconductor substrate is etched by using a resulting resist pattern as a mask. The water-soluble crosslinking agents used as the second resist include urea crosslinking agents such as urea, alkoxymethylene ureas, N-alkoxymethylene ureas, ethyleneurea, ethylene urea carboxylates and the like, melamine crosslinking agents such as melamine, alkoxymethylene melamines and the like, and amino crosslinking agents such as benzoguanamine, glycoluril and the like. Examples of water-soluble resist materials usable as the second resist include, aside from the water-soluble crosslinking agents used singly or in combination, the mixtures of these resins and crosslinking agents. The material for the first photoresist may be one which makes use of a mechanism capable of generating an acidic component inside the photoresist by an appropriate thermal treatment, and may be either a positive or negative photoresist. Examples of photoresist include novolac resin and a naphthoquinonediazide photosensitive agent. A chemically amplified resist making use of an acid generating mechanism may also be used as the first photoresist.

Ishibashi et al., U.S. Pat. No. 6,319,853, issued Nov. 20, 2001, discloses a method of producing a pure resist pattern having superior topography smaller than the limit of wavelength of exposure light. A first photoresist pattern containing material capable of producing an acid on exposure to light is coated with a second resist containing material which causes a crosslinking reaction in the presence of an acid. An acid is produced in the photoresist pattern by exposing the pattern to light, thus forming a crosslinked layer along the boundary surface between the first resist pattern and the second resist pattern. As a result, the second resist pattern which is greater than the first resist pattern is formed.

Tanaka et al., U.S. Pat. No. 6,593,063, issued Jul. 15, 2003, discloses a first resist layer capable of generating an acid formed on a semiconductor base and is developed in a shortened development time than usual. The first resist pattern is covered with a second resist layer containing a material capable of crosslinking in the presence of an acid. The acid is generated in the first resist pattern by application of heat or by exposure to light, and a crosslinked layer is formed in the second resist pattern at the interface with the first resist pattern as a cover layer for the first resist pattern, thereby the first resist pattern is caused to be thickened. The non-crosslinked portion of the second resist pattern is removed and the fine resist pattern is formed. The hole diameter of the resist pattern can be reduced, or the isolation width of a resist pattern may be produced utilizing this method.

### SUMMARY OF THE INVENTION

A process of forming a fine pattern comprising:

forming a first photoresist layer over a first layer of a semiconductor device;

exposing portions of the first photoresist layer causing a photochemical reaction therein;

prior to developing the first photoresist layer, forming a second photoresist layer over the first photoresist layer;

and wherein at least one of the first photoresist layer and second photoresist layer comprises a photo base generator.

Other embodiments of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1A illustrates a known method of making a semiconductor device including providing a first sacrificial layer over a first layer to be etched.

FIG. 1B illustrates a known method of making a semiconductor device including selectively exposing portions of the first sacrificial layer.

FIG. 1C illustrates a known method of making a semiconductor device including removing the exposed portion of the first sacrificial layer providing openings therein.

FIG. 1D illustrates a known method of making a semiconductor device including treating the first sacrificial layer.

FIG. 1E illustrates a known method of making a semiconductor device including forming a first photoresist layer over the first sacrificial layer.

FIG. 1F illustrates a known method of making a semiconductor device exposing portions of the first photoresist layer.

FIG. 1G illustrates a known method of making a semiconductor device including forming openings in the first photoresist layer that communicate with at least one opening in the first sacrificial layer.

FIG. 1H illustrates a known method of making a semiconductor device including etching openings in the first layer.

FIG. 1I illustrates a known method of making a semiconductor device including removing the first photoresist layer and the first sacrificial layer.

FIG. 2A illustrates a known method of making a semiconductor device including providing a first layer to be etched, a first sacrificial layer over the first layer, and a second sacrificial layer over the first sacrificial layer.

FIG. 2B illustrates a known method of making a semiconductor device including selectively exposing portions of the second sacrificial layer.

FIG. 2C illustrates a known method of making a semiconductor device including removing the exposed portion of the second sacrificial layer providing openings therein.

FIG. 2D illustrates a known method of making a semiconductor device including etching openings through the first sacrificial layer.

FIG. 2E illustrates a known method of making a semiconductor device including forming a first photoresist layer over the first sacrificial layer.

FIG. 2F illustrate a known method of making a semiconductor device including forming a first photoresist layer over the first sacrificial layer.

FIG. 2G illustrates a known method of making a semiconductor device including forming openings in the first photoresist layer that communicate with at least one opening in the first sacrificial layer.

FIG. 2H illustrates a known method of making a semiconductor device including etching openings in the first layer.

FIG. 2I illustrates a known method of making a semiconductor device including removing the first photoresist layer and the first sacrificial layer.

FIG. 3A illustrates a prior art method of forming a photoresist structure including depositing a first photoresist layer on a first layer.

FIG. 3B illustrates a prior art method including exposing, developing and patterning portions of the first photoresist layer.

FIG. 3C illustrates a prior art method including depositing a second photoresist layer over the structure of FIG. 3B.

FIG. 3D illustrates a prior art method including heating features formed by the first photoresist layer to cause an acid to be diffused from the features and crosslinked with the second photoresist layer along the boundary surfaces of the first photoresist features.

FIG. 3E illustrates a step in a prior art method including developing a second photoresist layer to remove uncrosslinked portions and to produce a photoresist structure having a relatively narrow gap between adjacent photoresist.

FIG. 4A illustrates one embodiment according to the present invention including forming a first photoresist layer over a first layer of a semiconductor device.

FIG. 4B illustrates one embodiment according to the present invention exposing portions of the first photoresist layer.

FIG. 4C illustrates one embodiment according to the present invention including forming a second photoresist layer over the first photoresist layer.

FIG. 4D illustrates one embodiment according to the present invention including exposing portions of the second photoresist layer.

FIG. 4E illustrates one embodiment according to the present invention including baking the semiconductor device.

FIG. 4F illustrates one embodiment according to the present invention including developing the first photoresist layer and the second photoresist layer.

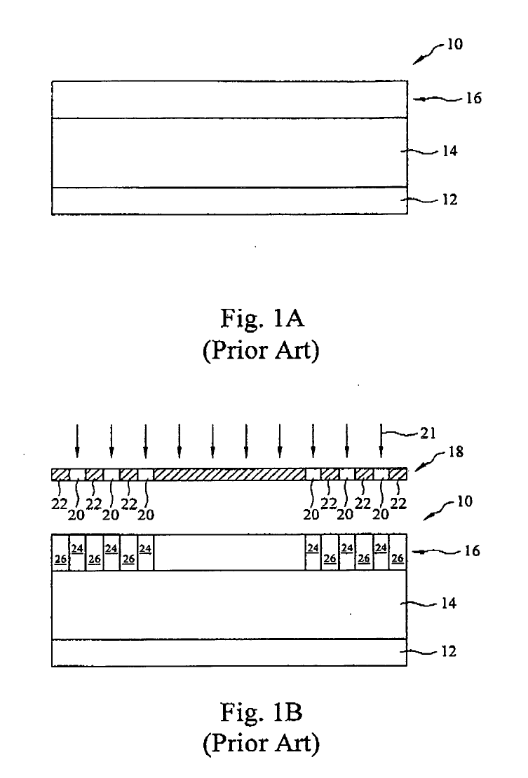

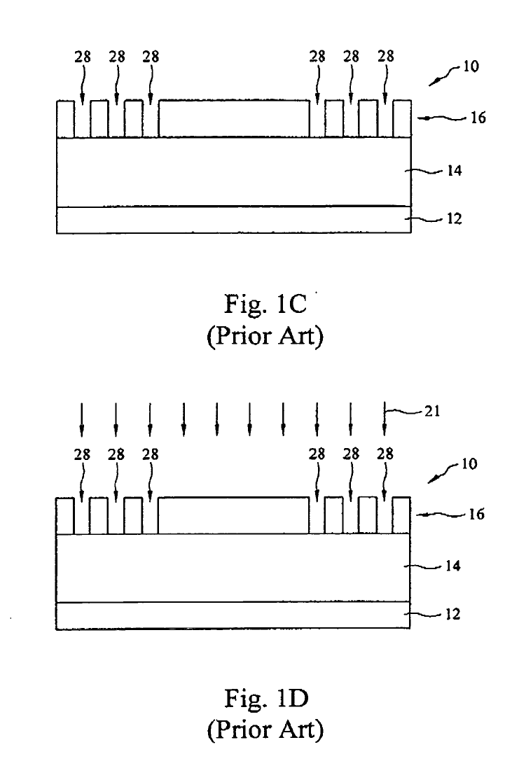

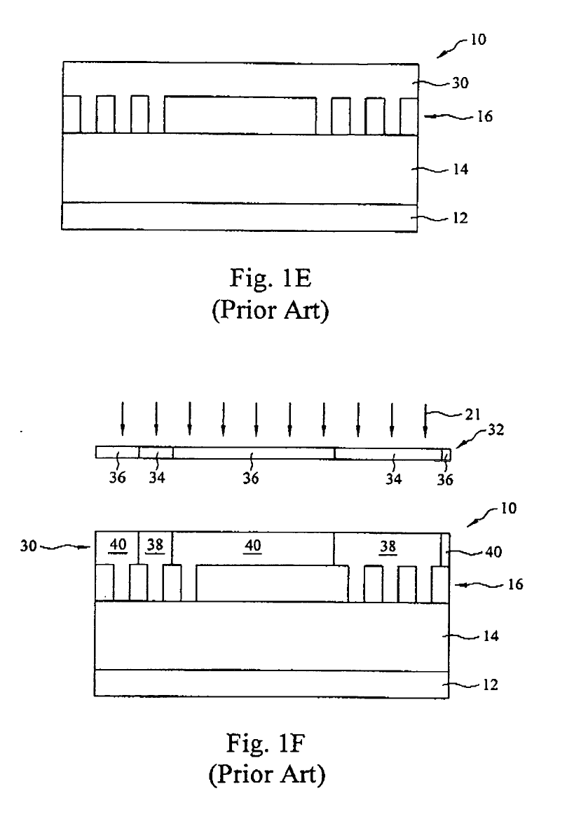

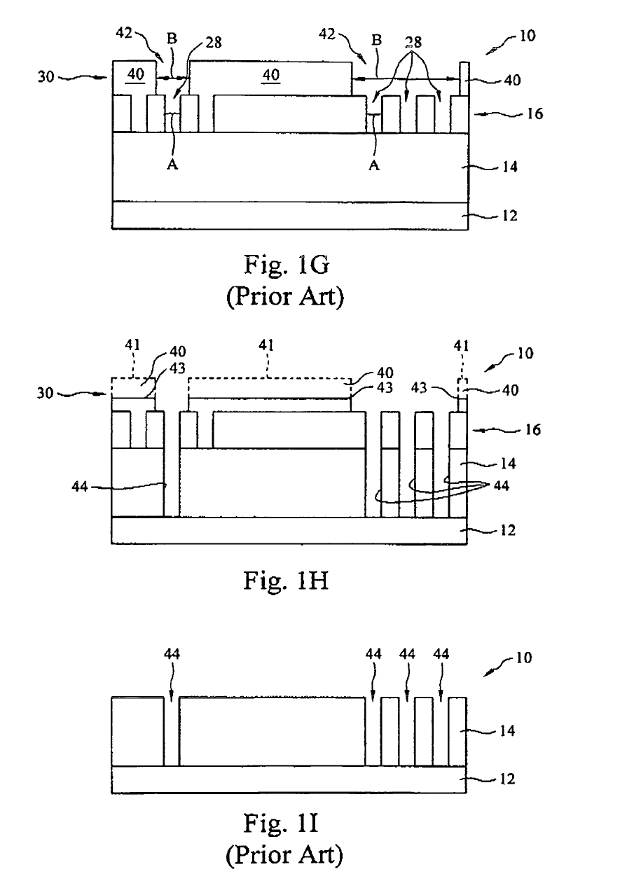

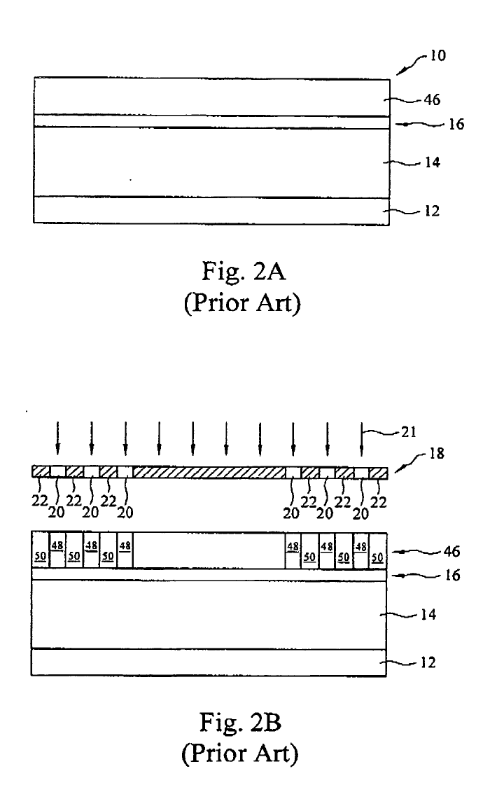

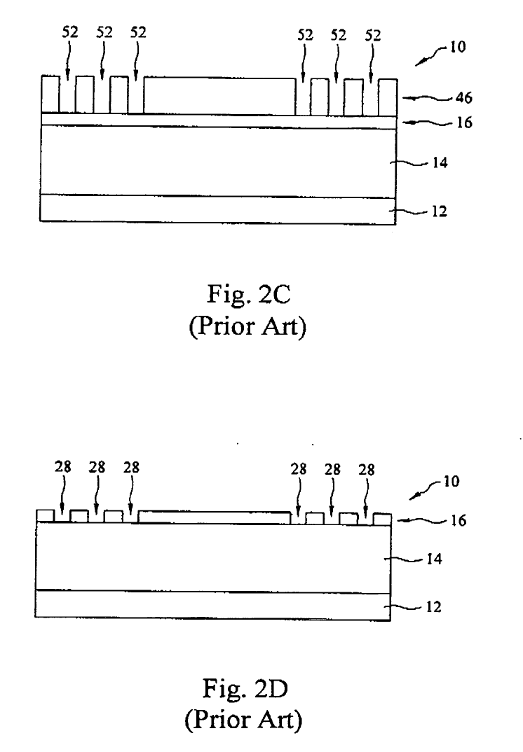

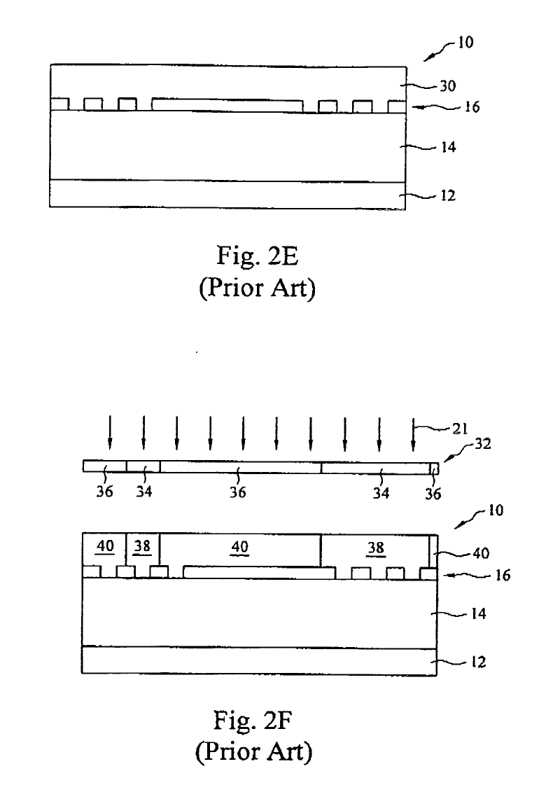

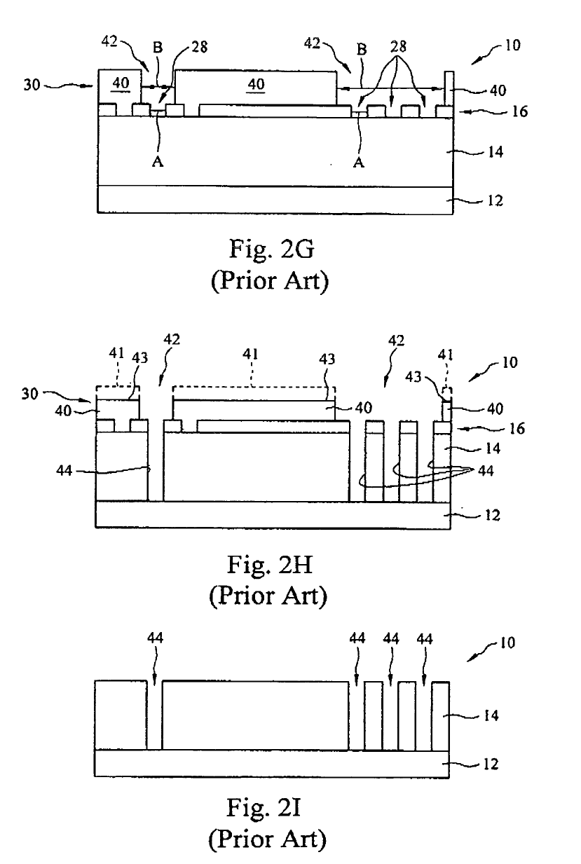

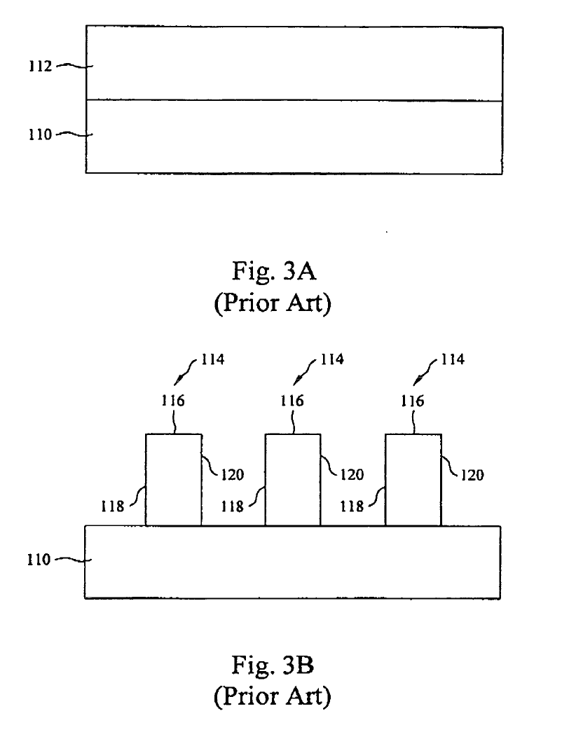

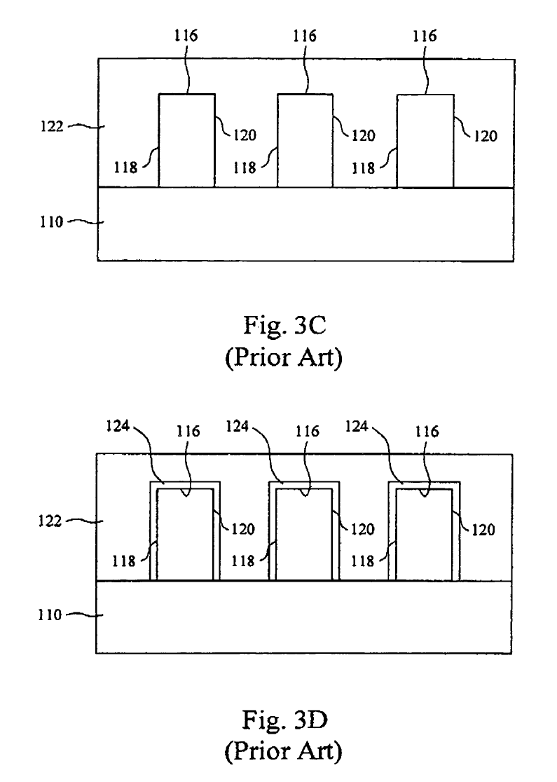

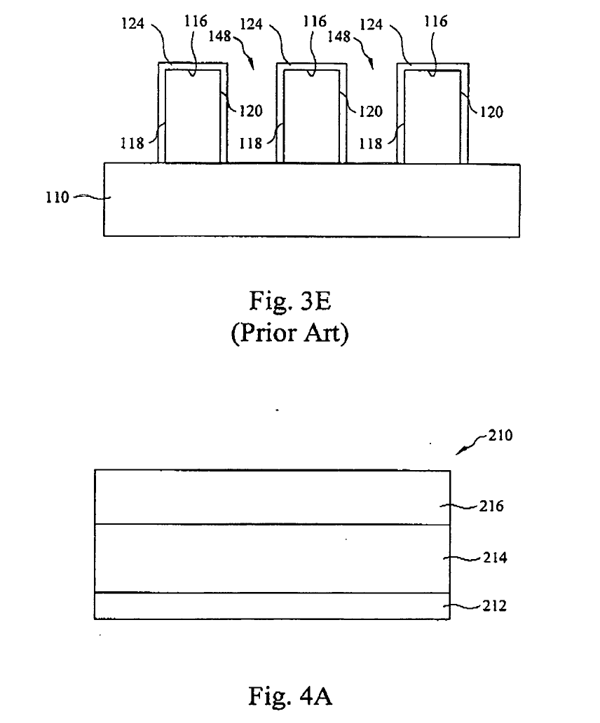

### DETAILED DESCRIPTION OF THE PREFERRED EMBODIMENTS

The following description of the preferred embodiment(s) is merely exemplary in nature and is in no way intended to limit the invention, its application, or uses.

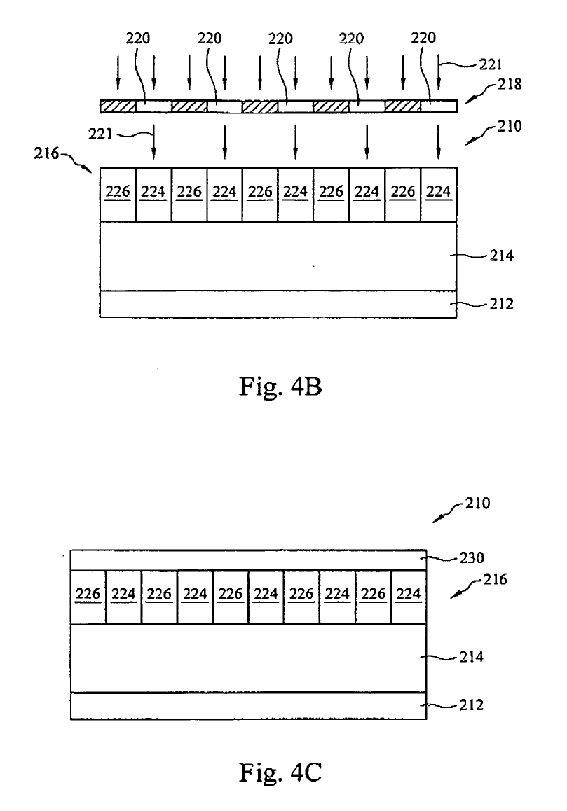

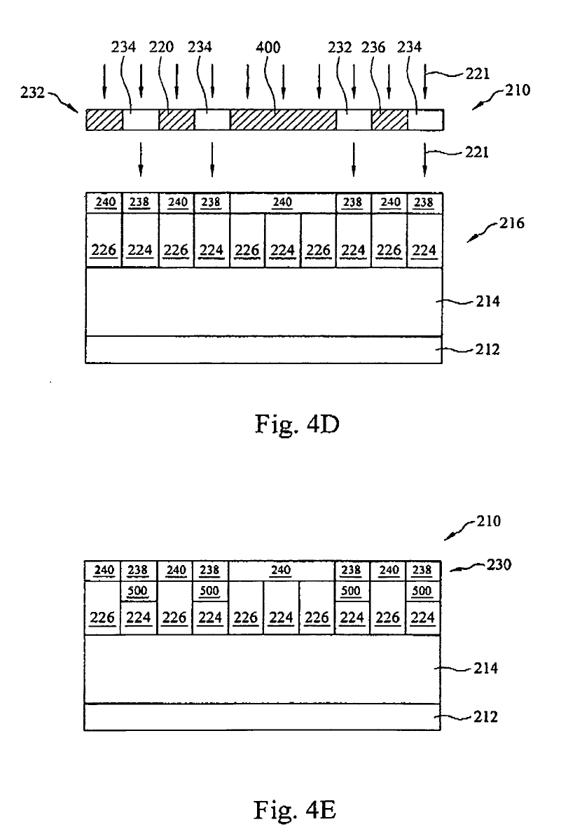

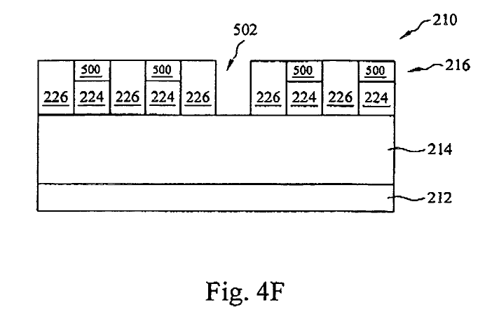

Referring now to FIGS. 4A-F, a known method of making a semiconductor device 210 includes providing a first layer 214 to be etched or otherwise further treated or further processed which may overlie a substrate 212 which may be a semiconductor wafer. Alternatively, the first layer 214 may be a semiconductor wafer. The substrate 212 may be any material known to those skilled in the art for making semiconductor devices including, but not limited, to silicon, germanium, silicon and germanium, gallium arsenate, silicon carbide and silicon germanium. The first layer 214 to be etched treated or treated may be an electrically conductive material, a dielectric or a semiconductor substrate. The first layer 214 to be etched, treated or further processed may be a dielectric such as silicon dioxide, or a low dielectric constant material such as SiOC, SiOF, SiC, SiCN. A first photoresist layer 216 is provided over the first layer 214 to be etched as shown in FIG. 4A. The first photoresist layer 216 may be a negative photoresist wherein exposed parts of the negative photoresist become cross-linked and polymerized due to the photochemical reaction, which hardens and remains after development, whereas the unexposed parts are dissolved by the developer solution. Alternatively, the first photoresist layer 216 may be a positive photoresist material, for example, wherein the main component is a novolac resin, and wherein the exposed parts' cross-links break down and become softened due to the photochemical reaction known as photosolubilization and are dissolved by the developer solution and the unexposed parts remain. The first photoresist layer 216 may include a photo acid generator that produces an acid upon exposure to heat or certain light, or the first photoresist layer 216 may include a photo base generator that produces a base upon exposure to heat or certain light.

Optionally, the first photoresist layer 216 may be baked to evaporate solvents and to densify the photoresist. Referring now to FIG. 4B, a first mask 218 is provided and includes transparent portions 220 for transmitting light therethrough and non-transparent portions 222 for blocking light. Light as indicated by the arrows labeled 221 is shown through the first mask 218 exposing portions of the first photoresist layer 216. The first photoresist layer 216 now includes light exposed portions 224 and unexposed portions 226.

Thereafter, without developing the first photoresist layer 216, a second photoresist layer 230 is formed over the first photoresist layer 216 as shown in FIG. 4C. The second photoresist layer 230 may be a negative photoresist wherein exposed parts of the negative photoresist become cross-linked and polymerized due to the photochemical reaction, which hardens and remains after development, whereas the unexposed parts are dissolved by the developer solution. Alternatively, the second photoresist layer 230 may be a positive photoresist material, for example wherein the main component is a novolac resin, and wherein the exposed parts' cross-links break down and become softened due to the photochemical reaction known as photosolubilization and are dissolved by the developer solution and the unexposed parts remain. The second photoresist layer 230 may include a photo acid generator that produces an acid upon exposure to heat or certain light, or the second photoresist layer 230 may include a photo base generator that produces a base upon exposure to heat or certain light. The first photoresist layer 216 may include the opposite photo generator from the second photoresist layer 230. Furthermore, the photoresist layer 216 and 230 also include a cross-linking agent that cross links the photoresist material upon exposure to an acid or a base. For example, the first photoresist layer 216 may include a photo acid generator and a cross-linking agent activated by a base, and the second photoresist layer 230 may include a photo base generator or a cross-linking agent activated by an acid; and conversely, the first photoresist layer 216 may include a photo base generator and a cross-linking agent activated by an acid, and the second photoresist layer 230 may include an photo acid generator or a cross-linking agent activated by a base. The second photoresist layer 230 may be water soluble or with different solvent than first photoresist layer 216. The second photoresist layer 230 may also produce a base on exposure to heat or light, wherein the base neutralizes the acid produced upon expose of a first photoresist that is a positive photoresist.

Referring now to FIG. 4D, thereafter, a second mask 232 which includes transparent portions 234 for transmitting light therethrough and non-transparent portions 236 for blocking light is positioned over the structure of FIG. 4C and light is transmitted through the mask creating exposed portions 238 in the first photoresist and unexposed portions 240 in the first photoresist. As will be appreciated from FIG. 4D, at least one of the transparent portions 234 of the second mask 232 or at least one of the light blocking portions 400 of the second mask 232 extends across two adjacent exposed portions of the first photoresist layer 216 or across two adjacent unexposed portion of the first photoresist layer 216. .

Referring now to FIG. 4E, thereafter, the semiconductor device 210 of FIG. 4D is exposed to heat, for example in a post exposure bake process causing a base to be released from the second photoresist layer 230, wherein the base reacts with acid produced in the exposed portion of the first photoresist layer 216 causing at least an upper portion 500 of the exposed portion of the first photoresist layer 216 to be neutrally without cleavage by acid. The un-cleavage positive polymer is not soluble in the developer so that the upper portions 500 are not soluble in the developer.

Thereafter, as shown in FIG. 4F, the semiconductor device is devolved in a water based developer that removes the second photoresist layer 230. The developer also removes unprotected, unpolymerized portions 502 (exposed portions in the case of a negative photoresist) of the first photoresist layer, but does not remove the upper portions 500, unpolymerized portion 224 and polymerized portions 226 (unexposed portions in the case of a negative photoresist) of the first photoresist layer 216. An opening 502 may be provided through the first photoresist layer 216 after developing.

In another embodiment as also shown in FIG. 4F, the semiconductor device is devolved in a water based developer that removes the second photoresist layer 230. The developer also removes unprotected, unpolymerized (polarized, developer soluble) portions 502 (exposed portions in the case of a positive photoresist) of the first photoresist layer, but does not remove the upper polymerized(non polarized, non-soluble to developer) portions 500, unpolymerized portion 224 and polymerized portions 226 (unexposed portions in the case of a positive photoresist) of the first photoresist layer 216. An opening 502 may be provided through the first photoresist layer 216 after developing.

The description of the invention is merely exemplary in nature and, thus, variations that do not depart from the gist of the invention are intended to be within the scope of the invention. Such variations are not to be regarded as a departure from the spirit and scope of the invention.

What is claimed is:

1. A process of forming a fine pattern comprising:
forming a first photoresist layer over a first layer of a semiconductor device;
exposing portions of the first photoresist layer causing a photochemical reaction therein; and
prior to developing the first photoresist layer, forming a second photoresist layer over the first photoresist layer;
wherein at least one of the first photoresist layer and second photoresist layer comprises a photo base generator.

2. A process as set forth in claim 1 wherein the first photoresist layer comprises a positive photoresist material.

3. A process as set forth in claim 1 wherein the second photoresist layer comprises a positive photoresist material.

4. A process as set forth in claim 1 wherein the second photoresist layer comprises a negative photoresist material.

5. A process as set forth in claim 1 wherein the second photoresist layer comprises at least one of a photo acid generator and a photo base generator.

6. A process as set forth in claim 1 wherein the second photoresist layer comprises a TMAH soluble polymer material.

7. A process as set forth in claim 1 further comprising exposing portions of the second photoresist layer causing a photochemical reaction therein.

8. A process set forth in claim 1 further comprising exposing portions of the second photoresist layer causing a photochemical reaction therein

9. A process as set forth in claim 1 wherein the first photoresist and second photoresist comprises different solvents.

10. A process of forming a fine pattern comprising:
forming a first photoresist layer over a first layer of a semiconductor device;
exposing portions of the first photoresist layer causing a photochemical reaction therein; and
prior to developing the first photoresist layer, forming a second photoresist layer over the first photoresist layer;
wherein the second photoresist layer comprises a photo base generator.

11. A process as set forth in claim 9 wherein the second photoresist layer is water soluble.

12. A process as set forth in claim 9 further comprising exposing the second photoresist layer to release a base therefrom.

13. A process as set forth in claim 9 further comprising baking the second photoresist layer at a first temperature.

14. A process as set forth in claim 13 further comprising baking the second photoresist layer at a second temperature, and wherein the second temperature is greater than the first temperature.

15. A process as set forth in claim 9 further comprising exposing portions of the second photoresist layer causing a photochemical reaction therein.

16. A method of forming a fine pattern comprising:
forming a first photoresist layer over a first layer of a semiconductor device;
exposing portions of the first photoresist layer causing a photochemical reaction therein; and
prior to developing the first photoresist layer, forming a second photoresist layer over the first photoresist layer, the second photoresist comprising a negative photoresist material.

17. A process as set forth in claim 16 wherein the first photoresist layer comprises a first solvent and the second photoresist layer comprising a second solvent different from the first solvent.

18. A process as set forth in claim 17 wherein the first photoresist layer comprises a first polymer and the second photoresist layer comprises a second polymer and wherein the first solvent cannot not be mixed with the second polymer and the second solvent cannot be mixed with the first polymer.

19. A process as set forth in claim 16 wherein the second photoresist layer comprises a water soluble polymer.

20. A process comprising:
forming a first photoresist layer over a first layer of a semiconductor device;
exposing portions of the first photoresist layer using a first mask causing an acid to be released from first portions of the first photoresist layer, and so that the first photoresist layer comprises acid containing and non acid containing portions;
prior to developing the first photoresist layer, forming a second photoresist layer over the first photoresist layer, the second photoresist layer comprises a photo base generator; and
exposing portions of the second photoresist layer using a second mask
causing the second photoresist layer to generate a base so that the base reacts with the acid in the first photoresist layer so that at least an upper portion of at least one of the first portions of the first photoresist layer is polymerized.

21. A process as set forth in claim 20 wherein the second photoresist material comprises a water soluble polymer and further comprises developing the second photoresist layer and the first photoresist layer with a water base developer to remove the second photoresist layer and unpolymerized portions of the first photoresist layer.

22. A process comprising:
forming a first photoresist layer over a first layer of a semiconductor device, the first photoresist layer comprising a positive photoresist material;
exposing portions of the first photoresist layer using a first mask causing an acid to be released from exposed portions of the first photoresist layer and so that spaced apart unexposed-polymerized portions are separated by an exposed portion having the acid therein;
prior to developing the first photoresist layer, forming a second photoresist layer over the first photoresist layer, the second photoresist layer comprises a photo base generator, exposing portions of the second photoresist layer using a second mask;
causing the second photoresist layer to generate a base so that the base reacts with the acid in the exposed portions of the first photoresist layer so that at least an upper portion of the exposed portion of the first photoresist layer is polymerized, and wherein the upper portion extends between the spaced apart unexposed polymerized portions of the first photoresist layer, and wherein the exposed portion under the upper portion is protected.

23. A process as set forth in claim 22 further comprising baking the semiconductor device after exposing the second photoresist layer.

24. A process as set forth in claim 22 further comprising developing the second photoresist layer and the first photoresist layer removing any unprotected portion of the first photoresist layer.

25. A process as set forth in claim 22 wherein the second photoresist layer comprises a water soluble polymer.

26. A process as set forth in claim 24 wherein the second photoresist layer comprises a water soluble polymer, and so that the developing removes the entire second photoresist layer.

27. A process of forming a fine pattern comprising:
forming a first photoresist layer over a first layer of a semiconductor device;
exposing portions of the first photoresist layer causing a photochemical reaction therein;
prior to developing the first photoresist layer, forming a second photoresist layer over the first photoresist layer;
exposing portions of the second photoresist layer causing a photochemical reaction therein;
post exposure baking the first photoresist layer and the second photoresist layer;
developing the first photoresist layer and the second photoresist layer.

28. A process as set forth in claim 27 wherein the first photoresist layer comprises a positive photoresist material.

29. A process as set forth in claim 27 wherein the second photoresist layer comprises a positive photoresist material.

30. A process as set forth in claim 27 wherein the second photoresist layer comprises a negative photoresist material.

31. A process as set forth in claim 27 wherein the second photoresist layer comprises at least one of a photo acid generator and a photo base generator.

32. A process as set forth in claim 27 wherein the first photoresist and second photoresist comprised using different solvent.
